(19) United States
(12) Patent Application Publication
(10) Pub. No.: US 2016/0366774 A1
(43) Pub. Date: Dec. 15, 2016

(54) ELECTRONIC COMPONENT AND METHOD FOR MANUFACTURING ELECTRONIC MODULE

(71) Applicant: CANON KABUSHIKI KAISHA, Tokyo (JP)

(72) Inventors: Shin Hasegawa, Hadano-shi (JP); Fujio Ito, Yokohama-shi (JP); Takanori Suzuki, Tokyo (JP); Takao Toyoka, Atsugi-shi (JP); Tadashi Kosaka, Atsugi-shi (JP); Yasushi Kurihara, Kawasaki-shi (JP); Koji Tsuduki, Kawasaki-shi (JP)

(21) Appl. No.: 15/177,250

(22) Filed: Jun. 8, 2016

(30) Foreign Application Priority Data
Jun. 15, 2015 (JP) 2015-120405

(51) Int. Cl. H05K 5/02; H05K 5/03; H05K 5/00; H05K 1/18; H05K 3/34; H01L 27/146

(52) U.S. Cl. CPC H05K 5/02; H05K 3/3494; H01L 27/14618; H05K 5/0017; H05K 1/181; H01L 27/14683; H01L 27/14636; H05K 5/03; H05K 2201/10128; H05K 2201/10151; H05K 2201/10121

(57) ABSTRACT

An electronic component including an electronic device and a container accommodating the electronic device. The container includes a base portion including a first surface on which the electronic device is mounted and a second surface on an opposite side of the first surface, an opposing portion opposing the electronic device with a space in between, a frame portion surrounding the space between the base portion and the opposing portion, and a plurality of connecting portions that are positioned on the second surface and positioned in at least an orthographic projection area of the electronic device, the plurality of connecting portions being soldered to a wiring member. In the orthographic projection area of the electronic device, a thickness of the base portion in a central area is smaller than a thickness of the base portion in a peripheral area such that the second surface forms a concave surface.

### BACKGROUND OF THE INVENTION

Field of the Invention

The present technique relates to mounting an electronic component.

Description of the Related Art

An electronic component is manufactured by primarily mounting an electronic device on a mounting member and by secondarily mounting the electronic component on a wiring member. Japanese Patent Laid-Open No. 2013-243339 describes an electronic component in which an electronic device is mounted on a mounting member and in which the electronic device is sealed in an airtight manner with a lid. The electronic component is secondarily mounted by bonding external terminals (connecting portions) provided on a back side of the electronic component to a wiring member by reflow soldering.

As in Japanese Patent Laid-Open No. 2013-243339, in an electronic component having an air tight space therein, there are cases in which, when performing reflow soldering, the space inside is expanded by heat and a back side of the electronic component is expanded towards a wiring member. In such a case, the distances between terminals provided on the back side of the electronic component and terminals of the wiring member may differ in each terminal, and the reliability of the solder bonding may be compromised.

Accordingly, the present technique provides an electronic component and a method for manufacturing an electronic module, which improves the connection of the connecting portions.

### SUMMARY OF THE INVENTION

The present technique provides an electronic component including an electronic device and a container accommodating the electronic device. The container includes a base portion including a first surface on which the electronic device is mounted and a second surface that is on an opposite side of the first surface, an opposing portion that opposes the electronic device, a frame portion that surrounds the space between the base portion and the opposing portion, and a plurality of connecting portions that are disposed on the second surface and disposed in at least an orthographic projection area of the electronic device, the plurality of connecting portions being bonded to a wiring member. In the orthographic projection area of the electronic device, a thickness of the base portion in a central area is smaller than a thickness of the base portion in a peripheral area such that the second surface forms a concave surface.

Further features of the present invention will become apparent from the following description of exemplary embodiments with reference to the attached drawings.

### BRIEF DESCRIPTION OF THE DRAWINGS

FIGS. 1A to 1C are schematic diagrams for describing an example of an electronic component.

FIGS. 2A to 2H are schematic diagrams for explaining an example of a method for manufacturing the electronic component and an electronic module.

FIGS. 3A to 3D are schematic diagrams for describing a comparative example.

### DESCRIPTION OF THE EMBODIMENTS

Hereinafter, a mode for carrying out the present technique will be described with reference to the drawings. Note that in the following description and in the drawings, components that are common throughout the plurality of drawings are attached with common reference numerals. Accordingly, common components will be described while referring to the plurality of drawings, and description of the components attached with common reference numerals will be omitted as appropriate.

Referring to the figures, the mode for carrying out the present technique will be described.

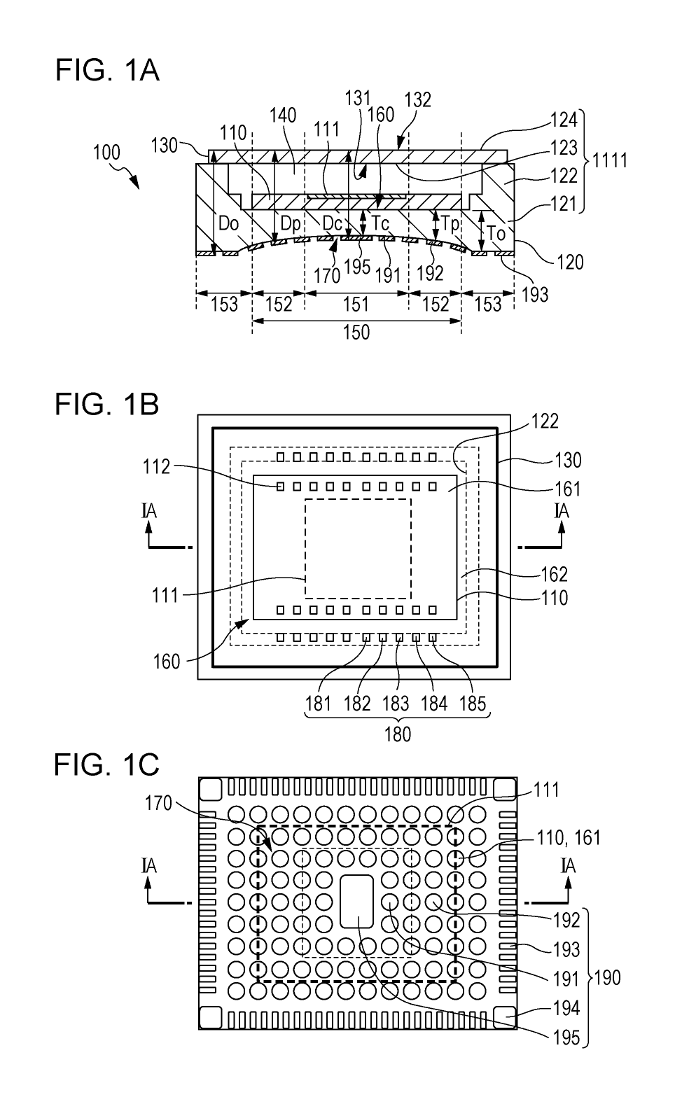

Referring to FIGS. 1A to 1C, an example of an electronic component 100 will be described. FIG. 1A is a cross-sectional view of the electronic component 100, FIG. 1B is a plan view of the electronic component 100, and FIG. 1C is a bottom view of the electronic component 100. Note that FIG. 1A is a cross-sectional view taken along line IA-IA in FIG. 1B and along line IA-IA in FIG. 1C.

The electronic component 100 includes an electronic device 110 and a container 1111 that accommodates the electronic device 110. A typical electronic device 110 is a semiconductor device; however, the electronic device 110 is not limited to a semiconductor device. The electronic device 110 may be an imaging device, a display device, or an MEMS device. As illustrated in FIG. 1B, the electronic device 110 includes a functional area 111. The functional area 111 is, in the case of an imaging device, an imaging area and is, in the case of a display device, a display area. Peripheral circuits (not shown), such as a drive circuit and a signal processing circuit for the functional area 111, and electrodes 112 for inputting and outputting signals are provided in the area other than the functional area 111. Among the two main surfaces of the electronic device 110, the surface on which the functional area 111 is located is referred to as the front side, and the surface on the other side of the front side is referred to as the back side. FIG. 1C illustrates the outlines of the electronic device 110 and the functional area 111. The outline of the electronic device 110 corresponds to the lateral sides of the electronic device 110.

The container 1111 includes a base portion 121, an opposing portion 123, and a frame portion 122. The base portion 121 includes a mounting surface 160 on which the electronic device 110 is mounted and a connection surface 170 located on the other side of the mounting surface 160. The back side of the electronic device 110 opposes the mounting surface 160 with a bonding material (not shown) in between. An orthographic projection area 150 of the electronic device 110 in the mounting surface 160 is a mounting area 161. An outer edge of the mounting surface 160 is defined by the frame portion 122. The mounting surface 160 may include a peripheral area 162 (see FIG. 1B) that ranges from the mounting area 161 to the outer edge. The opposing portion 123 opposes the surface of the electronic device 110 with a space 140 in between. When the electronic device 110 is an imaging device or a display device, the opposing portion 123 is optically transparent to visible light. The opposing portion 123 includes an inner surface 131 that is positioned on the electronic device 110 side and that faces the space 140, and an outer surface 132 that is on the opposite side with respect to the inner surface 131. The frame portion 122 surrounds the space 140 between the base portion 121 and the opposing portion 123. The space 140 may be an airtight space. The space 140 is vacuumed (a depressurized space) or is filled with gas, such as air or inert gas.

The container 1111 may include an internal connecting portion group 180 including a plurality of connecting portions 181, 182, 183, 184, and 185 on the space 140 side. Each connecting portion of the internal connecting portion group 180 is connected to the corresponding electrode 112 serving as a bonding pad of the electronic device 110 by wire bonding connection or by flip chip connection. When wire bonding connection is performed, each connecting portion of the internal connecting portion group 180 may be positioned outside the orthographic projection area 150 of the electronic device 110. In the present example, the internal connecting portion group 180 is disposed from the mounting surface 160 to a step portion of the stepped frame portion 122. When flip chip connection is performed, each connecting portion of the internal connecting portion group 180 may be positioned inside the orthographic projection area 150 of the electronic device 110. In such a case, the internal connecting portion group 180 may be provided in the base portion 121.

The container 1111 may include an external connecting portion group 190 including a plurality of connecting portions 191, 192, 193, 194, and 195 on the side opposite the space 140 side. Each connecting portion of the external connecting portion group 190 is electrically connected to the corresponding connecting portion of the internal connecting portion group 180. For example, the connecting portion 191 is electrically connected to the connecting portion 181, the connecting portion 182 to the connecting portion 192, the connecting portion 193 to the connecting portion 183, the connecting portion 184 to the connecting portion 194, and the connecting portion 185 to the connecting portion 195. The plurality of connecting portions 191, 192, and 195 are positioned on the connection surface 170 side and inside the orthographic projection area 150 of the electronic device 110, and are soldered to a wiring member that is provided separately from the electronic component 100. The wiring member is a circuit substrate, such as a printed circuit board using a flexible substrate or a rigid substrate.

The connecting portions 191 and 195 are positioned in a central area 151 of the orthographic projection area 150, and the connecting portions 192 are positioned in a peripheral area 152 of the orthographic projection area 150. Note that the central area 151 can be defined as an area corresponding to the functional area 111 of the electronic device 110, and the peripheral area 152 can be defined as an area other than the functional area 111 of the electronic device 110; however, the central area 151 and the peripheral area 152 are not limited to the above definitions. In another definition, the peripheral area 152 may be defined as a portion ranging from the edge of the electronic device 110 to a portion that is one fourth of the dimension of the electronic device 110, and the central area 151 may be defined as the area surrounded by the peripheral area 152. The container 1111 may include the connecting portions 193 and 194 that are positioned on the connection surface 170 side and in an outer area 153 that is outside the orthographic projection area 150 of the electronic device 110. Note that the connecting portions 191 to 195 may be connecting portions that contribute to the electrical connection; however, the connecting portions 191 to 195 may not contribute to the electrical connection and may be connecting portions for reinforcing mechanical connection or may be connecting portions for releasing heat. For example, the connecting portions 194 and 195 may have larger areas than those of the other connecting portions 191, 192, and 193 and may bear the role of mechanical and thermal connection. As the form of the connecting portions 191 to 195, a land grid array (LGA), a pin grid array (PGA), a ball grid array (BGA), a quad flat no-lead package (QFN), or a quad flat package (QFP) may be employed.

In the present example, the base portion 121, the frame portion 122, the internal connecting portion group 180, and the external connecting portion group 190 constitute a mounting member 120. The frame portion 122 may be, in the mounting member 120, a portion that is positioned in the outer area 153 of the electronic device 110. The opposing portion 123 may be, in a lid member 130 that is adhered to the frame portion 122 of the mounting member 120, a portion that is positioned in the orthographic projection area 150 of the electronic device 110. The lid member 130 includes a peripheral portion 124 at a portion around the opposing portion 123, and the peripheral portion 124 is bonded to the frame portion 122. Instead of providing the base portion 121 and the frame portion 122 in the mounting member 120, a lid member including the opposing portion 123 and the frame portion 122 may be adhered to a mounting member that includes the base portion 121. In the present example, the base portion 121 and the frame portion 122 of the mounting member 120 are formed in an integrated manner with the same type of material; however, the base portion 121 and the frame portion 122 may be formed of different types of materials and may be bonded to each other. The base portion 121 is formed of an insulating material, such as resin or ceramic. The frame portion 122 is formed of resin, ceramic, metal, or the like. While the mounting member 120 may be made of ceramic, it is desirable that the mounting member 120 is made of plastic with a lower rigidity. Regarding the mounting member 120, the base portion 121 and the frame portion 122 of the mounting member 120 may be formed in an integrated manner by resin molding.

Note that in a case in which the connection surface 170 is a flat surface, when the space 140 expands upon an increase in temperature of the electronic component 100, there may be cases in which the connection surface 170 is deformed to have a convex surface. Such an increase in temperature occurs during, for example, heat treating, such as reflow soldering performed when an electronic module is manufactured by mounting the electronic component 100 on a wiring member. Furthermore, the increase in temperature may occur due to heat generation of the electronic device 110 while a piece of electronic equipment on which the electronic component 100 is mounted is being used. Increase in temperature during fabrication may cause a bonding defect, such as a short circuit or an open circuit, while performing soldering and may reduce the yield. Increase in temperature during use may cause deterioration in the solder joints and may lower the reliability.

Conversely, in the electronic component 100 according to the present exemplary embodiment, the connection surface 170 has a concave surface that is recessed towards the mounting surface 160 side. By having the connection surface 170 have a concave surface in advance, when the temperature of the electronic component 100 increases, compared with a case in which the connection surface 170 has a flat surface in advance, the flatness of the connection surface 170 can be increased. As a result, reliability in the solder joint can be improved when performing heat treating during fabrication and when the temperature increases during use. Note that when the rigidities of the container 1111 and the wiring member are extremely high, for example, the deformation of the connection surface 170 upon increase in temperature may not be so large. In such a case as well, having the connection surface 170 have a concave surface is advantageous in reducing the stress caused on the electronic component 100.

A form of the connection surface 170 will be described in detail next. Regarding the shape of the base portion 121, FIG. 1A illustrates a thickness Tc of the central area 151, a thickness Tp of the peripheral area 152, and a thickness To of the outer area 153. The thickness of the base portion 121 is the distance between the mounting surface 160 and the connection surface 170. The thickness of the base portion 121 in the central area 151 is smaller than the thickness of the base portion 121 in the peripheral area 152 inside the orthographic projection area 150 of the electronic device 110. In other words, the thickness Tc of the base portion 121 in the central area 151 is smaller than the thickness Tp of the base portion 121 in the peripheral area 152 (Tc<Tp). By so doing, the connection surface 170 forms a concave surface that is recessed towards the mounting surface 160 side. In the example in FIG. 1A, the thickness of the base portion 121 becomes continuously smaller from the peripheral area 152 towards the central area 151. The thickness of the base portion 121 may become smaller in a stepwise manner from the peripheral area 152 towards the central area 151. In the present example, the thickness To of the base portion 121 in the outer area 153 of the orthographic projection area 150 is larger than the thickness Tp of the base portion 121 in the peripheral area 152 (Tp<To). However, the thickness To of the base portion 121 in the outer area 153 may be the same as the thickness Tp of the base portion 121 in the peripheral area 152 (Tp=To). In other words, in the connection surface 170, a portion corresponding to the central area 151 of the orthographic projection area 150 alone may be recessed with respect to the other portions. Alternatively, the entire connection surface 170 may be a concave surface. For example, the thickness of the portion corresponding to the outer area 153 may gradually become larger from the peripheral area 152. The cross-section of the concave surface may be appropriately selected from a stepwise-shape, and arc shape (including an elliptical arc), a parabolic shape, a catenary shape, and the like.

The mounting surface 160 may be flatter than the connection surface 170. The mounting surface 160 may have a flat surface or may have a concave surface. The mounting surface 160 may have a concave surface that is flatter than the concave surface of the connection surface 170.

In the orthographic projection area 150 of the electronic device 110, the thickness of the electronic component 100 in the central area 151 may be smaller than the thickness of the electronic component 100 in the peripheral area 152. In other words, a thickness Dc of the electronic component 100 in the central area 151 may be smaller than a thickness Dp of the electronic component 100 in the peripheral area 152 (Dc<Dp). In a case in which the electronic device 110 is an imaging device, desirably, the surface of the electronic device 110 on the opposing portion 123 side has a flat shape or a concaved shape. By so doing, influence of field curvature, which is one of the aberrations of a lens optical system, can be limited.

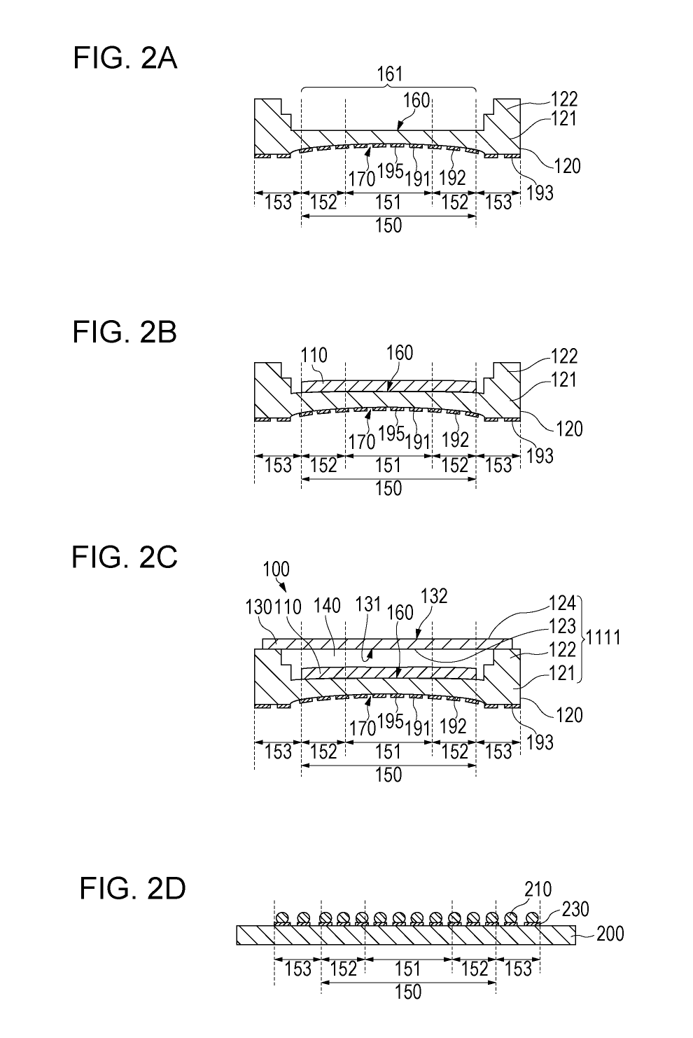

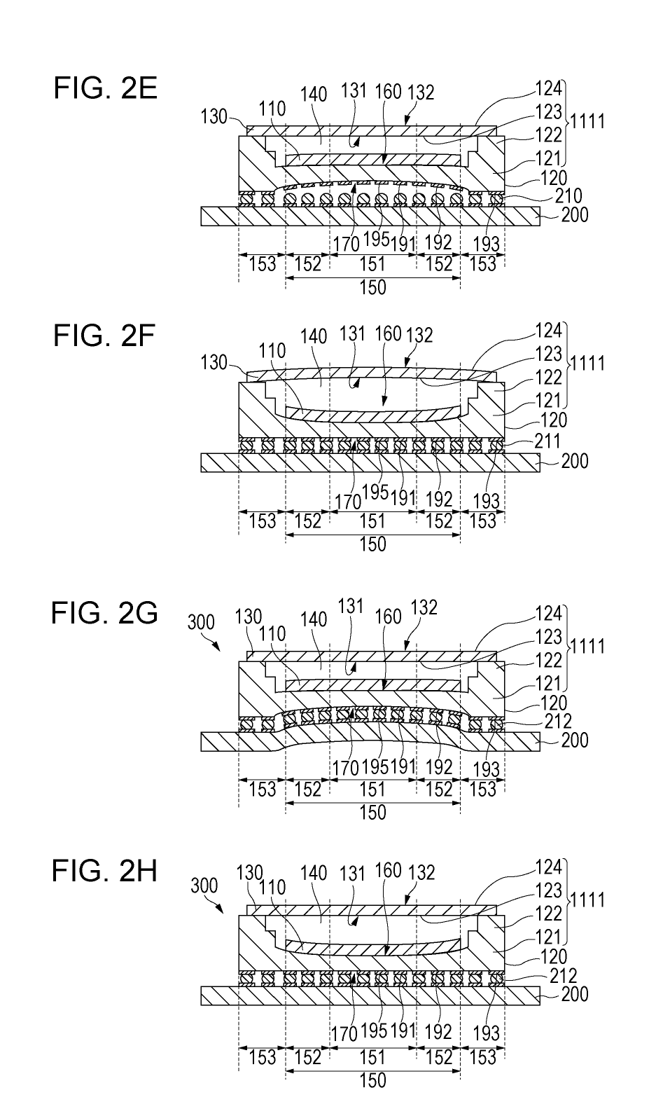

FIGS. 2A to 2H illustrate an example of a method for manufacturing the electronic component 100 and an electronic module 300. FIGS. 2A to 2C illustrate a manufacturing process of the electronic component 100, and FIGS. 2D to 2H illustrate a manufacturing process of the electronic module 300.

FIG. 2A illustrates a process of preparing the mounting member 120 including the base portion 121, the frame portion 122, and the connecting portions. A substantially flat mounting surface 160 on which the electronic device 110 is mounted is formed on the base portion 121 of the mounting member 120. The external connecting portion group including connecting portions 191, 192, 193, and 195 is formed on the connection surface 170 that is on the opposite side of the mounting surface 160. The mounting surface 160 includes the mounting area 161 on which the electronic device is mounted. The outline of the mounting area 161 matches the outline of the mounted electronic device. Regarding the thickness of the base portion 121 in the orthographic projection area 150 of the mounting area 161, the central area 151 is smaller than the peripheral area 152.

FIG. 2B illustrates a process of coating die bond paste or the like on the mounting area 161 of the mounting surface 160 of the base portion 121 and adhering the electronic device 110 to the mounting area 161. When the mounting surface 160 is formed of a convex surface, the flat electronic device 110 will be unstable when pasted on the convex surface such that a gradient is, disadvantageously, easily created. Accordingly, the mounting surface 160 is desirably a flat surface or a concave surface. When a thermosetting resin is used as the die bond paste and when the temperature of die bond paste is lowered to room temperature after the die bond paste has been thermally cured, there are cases in which the surface of the electronic device 110 becomes warped forming a convex surface. The above is due to a difference between the coefficient of linear expansion of the electronic device 110 and that of the mounting member 120. While the coefficient of linear expansion of silicon, which is a typical material of the electronic device 110, is about 3 ppm, even the coefficient of linear expansion of alumina ceramics, which has a relatively small coefficient of linear expansion among the materials for the mounting member 120, is 7 ppm. Since the coefficient of linear expansion of resin that is suitable for the mounting member 120 is even larger than that of ceramics, when resin is used as the material of the mounting member 120, it is desirable that the mounting surface 160 is not a convex surface.

FIG. 2C illustrates a process of fixing the lid member 130 to the mounting member 120 with an adhesive, such as a photosetting resin. In the above step, the electronic device 110 is sealed, together with gas in an air tight manner, inside the space 140 surrounded by the mounting member 120 and the lid member 130. Glass, crystal, or optical plastic may be used as the material of the opposing portion. Furthermore, air or inert gas, such as helium or nitrogen, may be used as the gas.

FIG. 2D illustrates a process of preparing a wiring member 200 and coating solder cream 210 on connecting portions 230 on the wiring member 200 with screen printing or the like. The wiring member 200 may be a flexible cable, a printed substrate, such as a glass epoxy substrate, or a ceramic substrate. The solder cream 210 may be a solder with a high melting point in which the melting point is 200° C. or higher, or may be a solder with a low melting point in which the melting point is 180 to 190° C.

FIG. 2E illustrates a process of stacking the electronic component 100 illustrated in FIG. 2C on the wiring member 200 prepared in the process illustrated in FIG. 2D. Positioning is performed so that the connecting portions 230 of the wiring member 200 and the connecting portions 191 to 195 of the electronic component 100 coincide with each other. In the connection surface 170, having a concave surface, there may be a case in which the connecting portions 191 to 195 and the pairing connecting portions 230 do not come in contact with the solder cream 210; however, there is no problem in particular. Note that in the process of coating the solder cream 210, the solder cream 210 may be coated on the connecting portion 191 to 195 of the electronic component 100 with screen printing or the like.

FIG. 2F illustrates a solder reflowing process. By heating the solder in the solder cream 210 to the melting temperature or higher, the solder cream 210 is melted between the connecting portions 230 of the wiring member 200 and the connecting portions 191 to 195 of the electronic component 100. The melted solder cream 210 is a molten solder 211. In the solder reflowing process, the electronic component 100 is exposed to a high-temperature atmosphere inside the furnace. The system for heating may be an infrared ray system, a vapor phase soldering (VPS) system, or a hot air system. Accordingly, when the gas inside the space 140 is heated and when the inner pressure of the space 140 increases and the space 140 is expanded according to the Boyle-Charles' law, the opposing portion 123 and the mounting member 120 may expand towards the outside. By having the connection surface 170 of the mounting member 120 be formed with a concave surface, the expansion is cancelled out. As a result, the shape of the connection surface 170 of the mounting member 120 becomes close to a flat surface. Subsequently, the connecting portions 191 to 195 and the connecting portions 230 of the wiring member 200 are connected to each other with the molten solder 211. As described above, even if there are connecting portions 191 to 195 that do not come in contact with the solder cream 210 before the heating in the solder reflowing process, with the expansion of the connection surface 170 in the above process, the connecting portions 191 to 195 that are not in contact with the solder cream 210 come into contact with the molten solder 211.

FIGS. 2G and 2H illustrate a process of cooling to room temperature after the solder reflowing process. By being cooled, the molten solder 211 becomes solidified forming solders 212 and the electronic component 100 and the wiring member 200 becomes bonded. With the above, the electronic module 300 is manufactured. Associated with the cooling of the electronic component 100, the pressure of the gas inside the space 140 decreases and the mounting member 120 starts to return to the shape before the bonding from the warped shape.

FIG. 2G illustrates a case in which the rigidity of the mounting member 120 is higher than the rigidity of the wiring member 200. In such a case, the amount of deformation of the wiring member 200 may be larger than the amount of deformation of the mounting member 120 during the cooling process. The electronic device 110 concavely deforming slightly or in the same manner with respect to the curve of the electronic device 110 of the electronic component 100 protruding towards the opposing portion 123 before bonding brings about an effect of cancelling out the field curvature, which is one of the aberrations of a lens optical system.

Conversely, FIG. 2H illustrates a case in which the rigidity of the mounting member 120 is lower than the rigidity of the wiring member 200. In such a case, the amount of deformation of the wiring member 200 may be smaller than the amount of deformation of the mounting member 120 during the cooling process. The electronic device 110 concavely deforming greatly with respect to the curve of the electronic device 110 of the electronic component 100 protruding towards the opposing portion 123 before bonding, brings about a greater effect of cancelling out the field curvature, which is one of the aberrations of a lens optical system. A combination of a mounting member 120 and a wiring member 200 in which the rigidity of the mounting member 120 is smaller than the rigidity of the wiring member 200 is, for example, a resin mounting member 120 and a glass epoxy wiring member 200. It is preferable that the wiring member 200 is made of ceramics since the rigidity of the wiring member 200 increases further.

Note that, optimally, the curved shape of the electronic device 110 extends along the curved surface of the field curvature of the optical system; however, a certain degree of non-coincidence with the curved surface of the field curvature can be permitted as long as the curved shape of the electronic device 110 has a concave shape. However, if the curved shape of the electronic device 110 is a convex shape, the peripheral portion will become out of focus and, accordingly, it is unfavorable with respect to image quality.

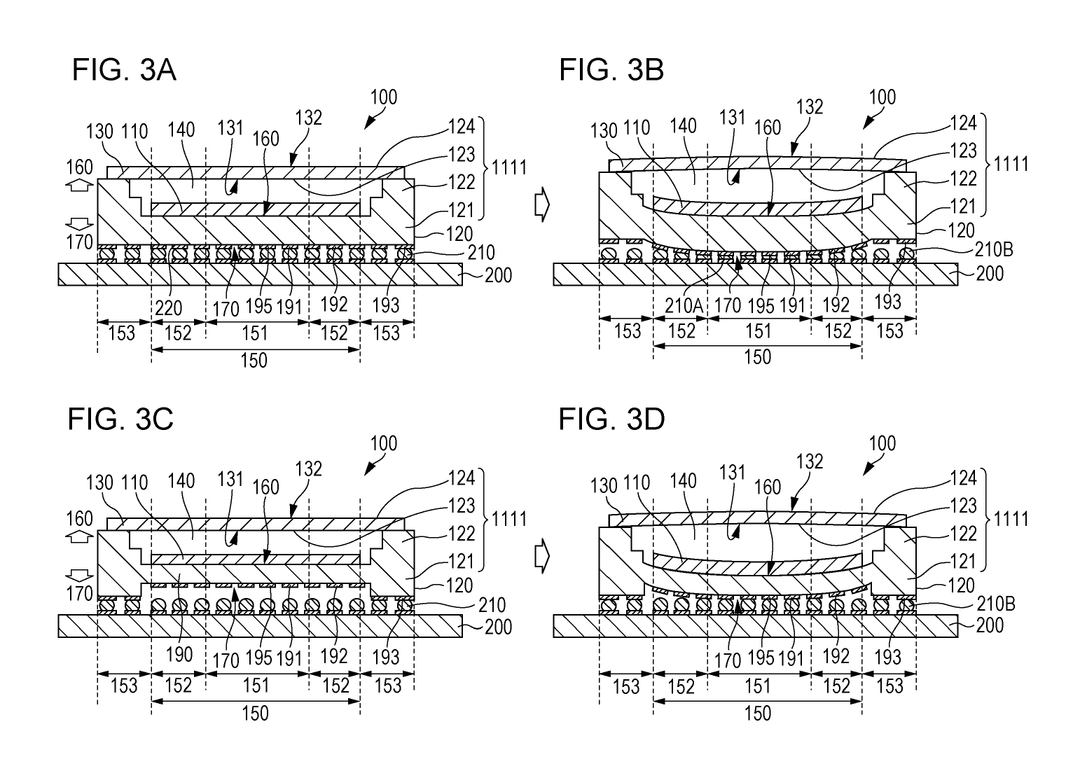

For comparison, a case in which the entire connection surface 170 is flat is illustrated in FIG. 3A. As illustrated in FIG. 3A, before heating, the connecting portions 230 of the wiring member 200 and the connecting portions 191 to 193 of the electronic component 100 on which reflow soldering is performed are in contact with the solder cream 210. However, as illustrated in FIG. 3B, since the gas inside the space 140 is heated and is expanded upon heating, the opposing portion 123 and the base portion 121 expand towards the outside. As a result, as illustrated in FIG. 3B, the solders 210B that are connected to the connecting portions 191 and 195 at the central area 151 may become squashed and a short circuit may occur. Furthermore, since the distance between the wiring member 200 and the electronic component 100 is large, bonding between the connecting portions 193 positioned in the outer area 153 and the solders 210B may not be achieved.

Furthermore, for comparison, a case in which the entire orthographic projection area 150 of the connection surface 170 is flat and is recessed with respect to the outer area 153 is illustrated in FIG. 3C. As illustrate in FIG. 3C, before heating, the connecting portions 230 of the wiring member 200 and the connecting portions 193 of the electronic component 100 are in contact with the solder cream 210. However, in the orthographic projection area 150, the connecting portions 191, 192, and 195 are not in contact with the solder cream 210. Since the gas inside the space 140 is heated and is expanded upon heating, the base portion 121 and the opposing portion 123 expand towards the outside. As a result, as illustrated in FIG. 3D, the connecting portions 191 and 195 positioned at the central area 151 and the connecting portions 193 positioned at the outer area 153 are connected by the solders 210B. However, since the distance between the wiring member 200 and the electronic component 100 is large, bonding between the connecting portions 192 positioned at the peripheral area 152 and the solders 210B may not be achieved.

Conversely, if the connection surface 170 in the orthographic projection area 150 forms a concave surface, the electronic component 100 expands and the connection surface 170 becomes almost flat upon heating such that a favorable bond can be formed.

As described above, the present technique is capable of improving the connection reliability of the connecting portions. The present technique is not limited to the matters described above and may be appropriately modified within the scope of the technical idea.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-120405, filed Jun. 15, 2015, which is hereby incorporated by reference herein in its entirety.

What is claimed is:

1. An electronic component comprising:
an electronic device;
a container accommodating the electronic device; and
the container including
a base portion including a first surface on which the electronic device is mounted and a second surface that is on an opposite side of the first surface,
an opposing portion that opposes the electronic device with a space in between,
a frame portion that surrounds the space between the base portion and the opposing portion, and
a plurality of connecting portions that are positioned on the second surface and positioned in at least an orthographic projection area of the electronic device, the plurality of connecting portions being soldered to a wiring member, wherein
in the orthographic projection area of the electronic device, a thickness of the base portion in a central area is smaller than a thickness of the base portion in a peripheral area such that the second surface forms a concave surface.

2. The electronic component according to claim 1, wherein
the first surface is flatter than the second surface.

3. The electronic component according to claim 1, wherein
the first surface forms a concave surface.

4. The electronic component according to claim 1, wherein
the thickness of the base portion becomes continuously smaller from the peripheral area towards the central area.

5. The electronic component according to claim 1, wherein
the base portion is formed of resin.

6. The electronic component according to claim 1, wherein
in the orthographic projection area of the electronic device, a thickness of the electronic component in the central area is smaller than a thickness of the electronic component in the peripheral area.

7. The electronic component according to claim 1, wherein
the electronic device is an imaging device or a display device.

8. A method for manufacturing an electronic module comprising:
bonding a plurality of connecting portions of an electronic component and a wiring member to each other by reflow soldering, wherein
the electronic component comprising:
an electronic device;
a container accommodating the electronic device; and
the container including
a base portion including a first surface on which the electronic device is mounted and a second surface that is on an opposite side of the first surface,
an opposing portion that opposes the electronic device with a space in between, and
a frame portion that surrounds the space between the base portion and the opposing portion, wherein
the plurality of connecting portions are positioned on the second surface and positioned in at least an orthographic projection area of the electronic device, and
in the orthographic projection area of the electronic device, a thickness of the base portion in a central area is smaller than a thickness of the base portion in a peripheral area such that the second surface forms a concave surface, before the bonding.

9. The method for manufacturing an electronic module according to claim 8, wherein
the second surface after bonding is flatter than the second surface before bonding.

10. The method for manufacturing an electronic module according to claim 8, wherein
the first surface after the bonding forms a concave surface.
